(19) United States
(12) Patent Application Publication
(10) Pub. No.: US 2023/0217791 A1
(43) Pub. Date: Jul. 6, 2023

(54) LIGHT EMITTING APPARATUS, DISPLAY APPARATUS, IMAGE PICKUP APPARATUS, ELECTRONIC APPARATUS, ILLUMINATING APPARATUS, AND MOVABLE OBJECT

(71) Applicant: CANON KABUSHIKI KAISHA, Tokyo (JP)

(72) Inventors: NORIFUMI KAJIMOTO, Kanagawa (JP); HIROAKI SANO, Kanagawa (JP); YOJIRO MATSUDA, Kanagawa (JP); TETSUO TAKAHASHI, Kanagawa (JP)

(21) Appl. No.: 18/182,179

(22) Filed: Mar. 10, 2023

Related U.S. Application Data
(63) Continuation of application No. PCT/JP2021/034046, filed on Sep. 16, 2021.

(30) Foreign Application Priority Data
Sep. 25, 2020 (JP) 2020-161441

(51) Int. Cl. H10K 59/80; H10K 59/38

(52) U.S. Cl. CPC H10K 59/879; H10K 59/38; H10K 59/12

(57) ABSTRACT

A light emitting apparatus including a substrate including a principal surface, a first light emitting element disposed on the principal surface, a second light emitting element disposed on the principal surface, a first lens and a second lens wherein a distance between a middle point of an emission area of the second light emitting element and an apex of the second lens is larger than a distance between a middle point of an emission area of the first light emitting element and an apex of the first lens, wherein the emission area of the second light emitting element is larger than the emission area of the first light emitting element, and wherein the lower electrode of the second light emitting element is larger than the lower electrode of the first light emitting element.

### CROSS-REFERENCE TO RELATED APPLICATIONS

This application is a Continuation of International Patent Application No. PCT/JP2021/034046, filed Sep. 16, 2021, which claims the benefit of Japanese Patent Application No. 2020-161441, filed Sep. 25, 2020, both of which are hereby incorporated by reference herein in their entirety.

### TECHNICAL FIELD

The present disclosure relates to a light emitting apparatus including an optical member, such as microlenses, as well as a display apparatus, an image pickup apparatus, an electronic apparatus, an illuminating apparatus, and a movable object including the same.

### BACKGROUND ART

Organic light emitting elements are devices including a first electrode, a second electrode, and an organic compound layer disposed therebetween and emits light when carriers are injected from the first electrode and the second electrode. The organic light emitting elements are lightweight and flexible devices. For this reason, display apparatuses including an organic light emitting element have recently attracted attention. To enable the display apparatuses to have high definition, a known method using an organic white light emitting element and a color filter (hereinafter referred to as “white + CF method”) is employed. The white + CF method forms an organic layer over the entire surface of the substrate and is therefore easier to achieve high definition in pixel size and pixel pitch than a method of forming organic layers for individual colors using a metal mask.

PTL 1 discloses a display apparatus including an organic light emitting diode (OLED) and an out-coupling component and the positional relationship between the out-coupling component and the emission area of the OLED.

PTL 2 discloses a light emitting device including a microlens array and a light emitting element group, which changes the distance between the central axis of the light emission of the light emitting element and the central axis of the lens.

PTL 1 describes the position relationship, such as the distance, between the light emitting element and the microlens for increasing the intensity in the frontal direction. PTL 2 describes changing the distance between the central axis of the light emitting element and the central axis of the microlens to uniformize the amount of light in the emitting direction.

However, PTLs 1 and 2 do not describe changing the size of the emission area in consideration of the power consumption and the display quality of the light emitting device.

### CITATION LIST

### Patent Literature

PTL 1 Japanese Patent Laid-Open No. 2017-017013 PTL 2 Japanese Patent Laid-Open No. 2020-004868

### SUMMARY OF INVENTION

The present disclosure is made in view of the above disadvantages. Accordingly, an aspect of the present disclosure is to provide a display apparatus that provides stable display quality regardless of the user’s gaze viewing position while improving the light use efficiency and reducing the power consumption using an optical member, such as microlenses.

The present disclosure provides a light emitting apparatus including a substrate including a principal surface, a first light emitting element disposed on the principal surface, a second light emitting element disposed on the principal surface, a first lens that receives light emitted from the first light emitting element, and a second lens that receives light emitted from the second light emitting element, wherein the first light emitting element and the second light emitting element each include a lower electrode, an upper electrode, and an organic compound layer disposed between the lower electrode and the upper electrode, wherein, in a direction parallel to the principal surface, a distance between a middle point of an emission area of the second light emitting element and an apex of the second lens is larger than a distance between a middle point of an emission area of the first light emitting element and an apex of the first lens, wherein the emission area of the second light emitting element is larger than the emission area of the first light emitting element, and wherein the lower electrode of the second light emitting element is larger than the lower electrode of the first light emitting element.

Further features of the present disclosure will become apparent from the following description of exemplary embodiments with reference to the attached drawings.

### BRIEF DESCRIPTION OF DRAWINGS

FIG. 1A is a cross-sectional view of an example of a first light emitting element of a light emitting apparatus according to an embodiment of the present disclosure.

FIG. 1B is a plan view of the first light emitting element in FIG. 1A.

FIG. 2A is a cross-sectional view of an example of a second light emitting element of the light emitting apparatus according to an embodiment of the present disclosure.

FIG. 2B is a plan view of the second light emitting element in FIG. 2A.

FIG. 3 is a cross-sectional view of a comparable example.

FIG. 4A is a plan view of a light emitting apparatus according to an embodiment of the present disclosure.

FIG. 4B is a cross-sectional view taken along line IVB-IVB in FIG. 4A.

FIG. 5 is a schematic cross-sectional view of an example of a light emitting apparatus according to an embodiment of the present disclosure.

FIG. 6 is a cross-sectional view illustrating the effect of the present disclosure.

FIG. 7 is a schematic diagram illustrating an example of a display apparatus according to an embodiment of the present disclosure.

FIG. 8A is a schematic diagram illustrating an example of an image pickup apparatus according to an embodiment of the present disclosure.

FIG. 8B is a schematic diagram illustrating an example of an electronic apparatus according to an embodiment of the present disclosure.

FIG. 9A is a schematic diagram illustrating an example of a display apparatus according to an embodiment of the present disclosure.

FIG. 9B is a schematic diagram illustrating an example of a foldable display apparatus according to an embodiment of the present disclosure.

FIG. 10A is a schematic diagram illustrating an example of an illumination system according to an embodiment of the present disclosure.

FIG. 10B is a schematic diagram of an example of an automobile including a lighting fixture for vehicles according to an embodiment of the present disclosure.

FIG. 11A is a diagram illustrating an example of a pair of smartglasses according to an embodiment of the present disclosure.

FIG. 11B is a diagram illustrating an example of a pair of smartglasses according to an embodiment of the present disclosure.

FIG. 12A is a conceptual diagram illustrating the relationship between a viewer and a display apparatus used together with an optical system in the case where the viewer’s gaze is at the center of the display panel.

FIG. 12B is a conceptual diagram illustrating the relationship between the viewer and the display apparatus used together with the optical system in the case where the viewer’s gaze is at an end of the display panel.

FIG. 13A is a diagram illustrating the relationship between the angle of view and the radiation angle of light at a display panel in the overall view condition and the gaze condition.

FIG. 13B is a diagram illustrating the relationship between the panel angle of view and the difference between the minimum radiation angle and the maximum radiation angle in the overall view condition and the gaze condition.

### DESCRIPTION OF EMBODIMENTS

A light emitting apparatus according to an embodiment of the present disclosure includes a substrate including a principal surface, a first light emitting element disposed on the principal surface, a second light emitting element disposed on the principal surface, a first lens that receives light emitted from the first light emitting element, and a second lens that receives light emitted from the second light emitting element, wherein, in a direction parallel to the principal surface, a distance between a middle point of an emission area of the second light emitting element and an apex of the second lens is larger than a distance between a middle point of an emission area of the first light emitting element and an apex of the first lens, and wherein the emission area of the second light emitting element is larger than the emission area of the first light emitting element.

The second light emitting element may be a light emitting element that emits light at a wide angle to the display apparatus. In the second light emitting element, the optical member is deviated to emit wide-angle light as compared with the first light emitting element. In other words, the distance between the middle point of the emission area of the second light emitting element and the apex of the second lens in a cross section including the lower electrode, the first optical member, and the second optical member is larger than the distance between the middle point of the emission area of the first light emitting element and the apex of the first lens in the cross section.

In this case, the range of the radiation angle of the second light emitting element needed to stabilize the display quality regardless of the user’s gaze position is larger than that of the first light emitting element. This is because the radiation angle depends on the positional relationship between the optical member and a minute light source in the emission area, and therefore the range of the radiation angle increases as the emission area increases.

The emission area of the second light emitting element is larger than that of the first light emitting element to stabilize the display quality regardless of the user’s gaze position. The larger emission area decreases the radiation intensity relative to the input current but stabilizes the display quality in a wide radiation angle range with the turn of the user’s eyeball.

In this specification, the lens may be an optical member, such as microlenses. The lens shape may be spherical or aspherical. The light emitting layer may be composed of an organic compound or an inorganic compound.

Embodiments will be described hereinbelow with reference to the drawings. It is to be understood that the following embodiments do not limit the invention. The embodiments describe a plurality of configurations, but not all of the configurations are required. The configurations may be freely combined. In the drawings, the same or similar components are denoted by the same reference signs, and duplicated descriptions may be omitted.

For example, in the white + CF method, the color filters may be color filters that allow red, green, and blue light to pass through. Addition and mixture of the colors of the subpixels allow the organic EL light emitting apparatus to display a full color image. The following embodiments show color filters that allow three colors of light to pass through as an example. However, this is illustrative only.

In this specification, the lens may be disposed on the light extraction side of the light emitting apparatus, and the convex side of the lens may be on the light extraction side. If the light emitting apparatus emits light from both the lower electrode side and the upper electrode side of the light emitting element, both sides can be referred to as the light extraction side. The microlenses may be spherical lenses, aspherical lenses, or digital microlenses.

Its planar arrangement may be any of a stripe arrangement, a square arrangement, a delta arrangement, and a Bayer arrangement. The delta arrangement is particularly desirable because microlenses with strong lens power and high light extraction efficiency can be disposed at high definition. Matrix arrangement of the main pixels allows the light emitting apparatus to have a large number of pixels.

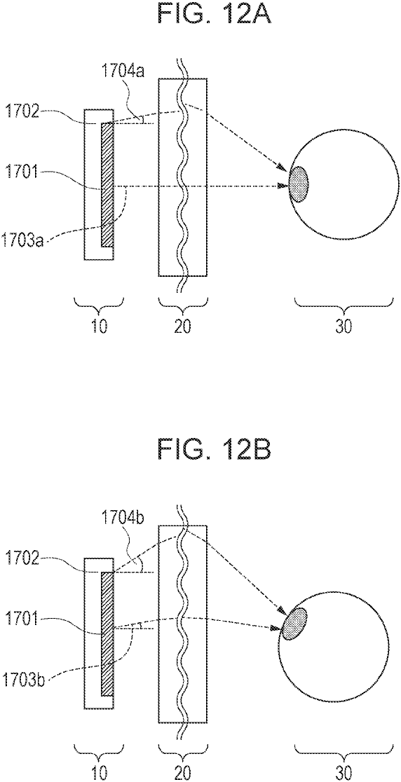

An example in which organic light emitting elements are used together with an optical system is a head mount display. FIGS. 12A and 12B are diagrams illustrating, in outline, light from the organic light emitting apparatus 10 to a user’s eyeball 30. FIG. 12A corresponds to a case where the user’s gaze is at a panel center 1701, which is referred to as “overall view condition”. The light from a panel end 1702 is recognized as a peripheral vision and therefore exhibits low sensitivity to a decrease in luminance and color misalignment. However, since the user uses the head mount display under an overall view condition for a long time, the display performance under the overall view condition is preferably maintained. In contrast, FIG. 12B corresponds to a case where the user turns the eyeball 30 to move the gaze portion, which is referred to as “gaze condition”. FIG. 12B illustrates a case in which the panel end 1702 is gazed at. The user does not gaze at the panel end 1702 for a long time but perceives the panel end 1702 with a central area of vision, which provides high sensitivity to a decrease in luminance and color misalignment. For this reason, head mount displays are preferably designed to maintain the display performance in the overall view condition and the gaze condition.

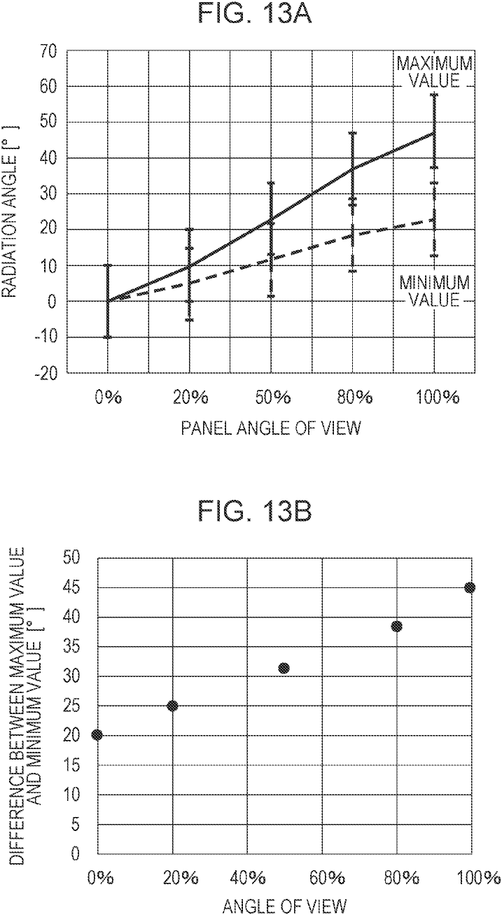

FIG. 13A shows the relationship between the angle of view at a panel and the radiation angle of light in the overall view condition and the gaze condition. An angle of view of 0% on the horizontal axis in FIG. 13A corresponds to the panel center 1701 in FIG. 12A, and a panel angle of view of 100% corresponds to the panel end 1702 in FIG. 12A. The solid line and the broken line in FIG. 13A correspond to radiation angles under the gaze condition and the overall view condition, respectively. The error bars indicate the displacement of the head mount from the user’s eyeball 30. The absolute value in FIG. 13A is variable according to the distance between the organic light emitting apparatus 10 and the eyeball 30, the field of view (FOV), and so on, but their relative relationship is invariable.

FIG. 13A shows that the radiation angle needed increases in both the overall view condition and the gaze condition as the panel angle of view increases. The radiation angle in the gaze condition is larger than that in the overall view condition by the amount corresponding to the turn of the eyeball 30. The tendency increases as the panel angle of view increases. FIG. 13B shows the relationship between the difference between the minimum radiation angle in the overall view condition and the maximum radiation angle in the gaze condition and the panel angle of view. FIG. 13B shows that the difference between the maximum angle and the minimum angle increases as the panel angle of view increases. The inventors have found that wider radiation angle characteristics are preferable closer to the panel end 1702. An embodiment of the present disclosure includes a first emission area and a second emission area surrounding the first emission area in the display area. The second emission area is larger than the first emission area, thereby improving the display quality.

The light emitting element may include a microlens. If the light emitting element includes a microlens, the light emitting apparatus may include a second light emitting element in which the distance between the central axis of the emission area and the central axis of the microlens is larger than that of the first light emitting element in a cross section perpendicular to the substrate principal surface. The second light emitting element may have an emission area larger than that of the first light emitting element.

The first light emitting element may have a first electrode larger than that of the second light emitting element. The electrode is not too much large with respect to the emission area.

### First Embodiment

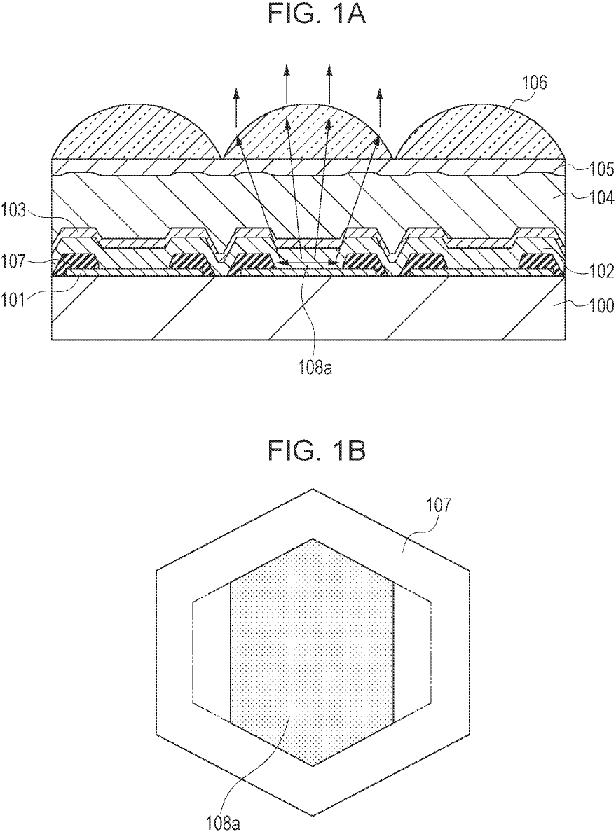

FIGS. 1A and 1B are diagrams showing a first light emitting element of a light emitting apparatus according to a first embodiment of the present disclosure. FIG. 1A is a cross-sectional view of the first light emitting element. FIG. 1B is a plan view of the first light emitting element in FIG. 1A.

The light emitting apparatus in FIG. 1A includes, on a substrate 100, a lower electrode 101, a functional layer 102 including a light emitting layer, an upper electrode 103, a protective layer 104, a planarizing film 105, a microlens 106, and an insulating layer 107 covering opposite ends of the lower electrode 101. Of the insulating layer 107, an insulating layer in contact with one end may be referred to as a first insulating layer, and an insulating layer in contact with the other end may be referred to as a second insulating layer. The insulating layer 107 is also referred to as a pixel separation film or bank. The cross-sectional view in FIG. 1A is a cross section perpendicular to the principal surface of the substrate 100. The plan view in FIG. 1B is a plan view observed from the direction perpendicular to the principal surface of the substrate 100. The principal surface of the substrate is provided with the light emitting element. The surface on which the light emitting element is provided may have an insulating film, such as an oxide film, between the substrate 100 and the light emitting element. The insulating film may have therein a transistor, a capacitative element, and a reflecting film.

The ends of the lower electrode 101 are in contact and covered with the insulating layer 107. An area of the lower electrode 101 not in contact with the insulating layer 107 may be in contact with the functional layer 102. The area where the lower electrode 101 and the functional layer 102 are in contact with each other is an emission area 108a that emits light by application of an electric field to the between the lower electrode 101 and the upper electrode 103.

The emission area 108a may be identified by observing light emission at application of an electric field from the same direction as in FIG. 1B. The emission area 108a may also be identified by measuring the distance form an end of the first insulating layer covering the left end of the lower electrode 101 to an end of the second insulating layer covering the right end of the lower electrode 101 in FIG. 1A. The ends of the insulating layer 107 may be contact points between the insulating layer 107 and the lower electrode 101.

FIG. 1A shows an example in which the positional relationship between the microlens 106 and the emission area 108a is optimized so that light is emitted to the front. Since the emission area 108a is smaller than an emission area 108b of the second light emitting element, almost all components are emitted to the front. In other words, the range of the panel radiation angle is relatively small.

In FIG. 1B, the emission area 108a is enclosed by the insulating layer 107. The emission area in this embodiment is hexagonal but may have another polygonal shape or a circular shape. For example, the emission area 108a may take a stripe arrangement in which rectangular red, green, and blue (RGB) emission areas are arranged for light emission.

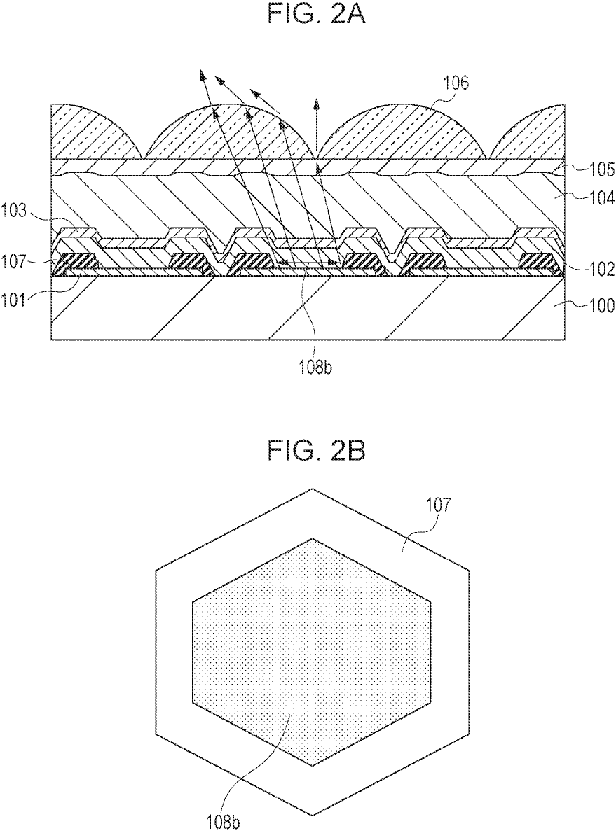

FIGS. 2A and 2B are diagrams illustrating the second light emitting element of the light emitting apparatus according to an embodiment of the present disclosure. FIG. 2A is a cross-sectional view of the second light emitting element. FIG. 2B is a plan view of the second light emitting element in FIG. 2A. The cross-sectional view and the plan view are the same as those of FIGS. 1A and 1B.

The second light emitting element has a configuration similar to that of the first light emitting element. The distance between the middle point of the emission area 108b and the apex of the microlens 106 of the second light emitting element in the direction parallel to the principal surface of the substrate 100 is larger than the distance between the middle point of the emission area 108a and the apex of the microlens 106 of the first light emitting element. In other words, assuming that the microlens 106 of the first light emitting element is in the normal position, the microlens 106 of the second light emitting element is deviated therefrom.

If the microlens 106 is a convex lens, the apex of the microlens 106 is farthest from the principal surface of the substrate 100 in a plane perpendicular to the principal surface. If the microlens 106 is a concave lens, the apex of the microlens 106 is closest to the principal surface of the substrate 100 in a cross section perpendicular to the principal surface. In other words, the apex of the lens is the center of the lens in a cross section parallel to the principal surface of the substrate 100.

The emission area 108b of the second light emitting element is larger than the emission area 108a of the first light emitting element. In other words, the emission area 108b in FIG. 2A is longer in line segment than the emission area 108a in FIG. 1A. In other words, the area where the functional layer 102 is in contact with the lower electrode 101 is large.

The radiation angle of light passing through the microlens 106 changes at the individual positions of point light sources in the emission area 108b as the emission area 108b is large. In other words, the range of the panel radiation angle is wide. The increase in the emission area 108b of the second light emitting element allows the display quality to be stabilized regardless of the user’s gaze position.

FIG. 2B illustrates an embodiment of the emission area 108b. In this embodiment, the emission area 108b is disposed such that two right and left sides in the plane of the drawing are disposed on the outer side of the hexagon than those of the emission area 108a. In other words, the emission area 108b of the second light emitting element is hexagonal, and at least one side of the hexagon is disposed outer side of the hexagon than that of the emission area 108a of the first light emitting element. The two sides of the hexagon are a pair of sides that are most distant from each other among the sides of the hexagon.

In this embodiment, two sides of the hexagon of the emission area 108a are arranged on the inner side of the hexagon than those of the emission area 108b. However, at least one side of a polygon may be disposed on the inner side of the polygon than that of the emission area 108b of the second light emitting element.

### Comparative Example

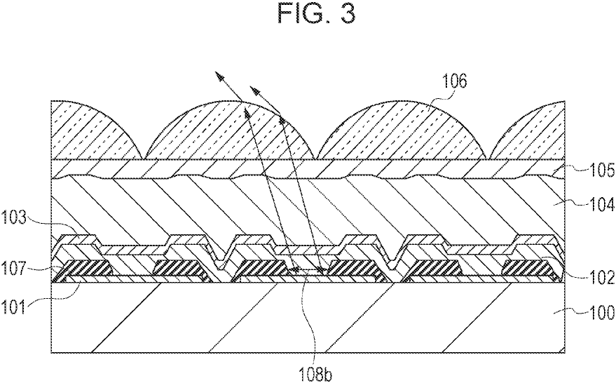

FIG. 3 is a cross-sectional view of a comparable example. In this example, the positional relationship between the emission area of the second light emitting element and the optical member differs from the positional relationship of the first light emitting element, but the emission area of the second light emitting element has the same size as the size of the emission area of the first light emitting element. The fact that the positional relationship between the second light emitting element and the optical member differs from that of the first light emitting element indicates that the optical members are out of alignment. The direction of the misalignment of the optical member may be a direction in which the light emitted from the light emitting layer is to be bent.

Since all the light from the emission area 108b is bent in one angular direction, as shown in FIG. 3, the distribution of the radiation angles is smaller than that in FIG. 2A. This can cause dark peripheral vision, which is undesirable for specifications where the overall view condition is important.

Thus, increasing the emission area 108b of the second light emitting element as in FIG. 2A provides a wide radiation angle range, allowing the display quality to be stabilized even if the user’s gaze changes in a wide range.

Many display apparatuses that use light directed in oblique directions with respect to the display surface in the peripheral area of the display apparatus include a display and an optical system, in which the user views the display through the optical system. With this configuration of the display apparatus, the first light emitting element capable of concentrating light to the front is often disposed in the panel center area. This is because, the luminance of the display apparatus is set for the value of the panel center. Not emitting unused light has the following advantages. For example, unused light entering an optical system 20 in FIGS. 12A and 12B becomes stray light, which may decrease the display quality. In the above embodiment, light that does not contribute to display is not emitted, which brings about the beneficial effect of reducing stray light.

This embodiment shows a light emitting apparatus including micro lenses as an example. Any small emission area that is less responsible for the light emission of the display apparatus may be used with or without an optical member such as microlenses.

For example, a light emitting apparatus includes a first emission area and a second emission area surrounding the first emission area, and a light emitting element in the second emission area may be required to have wide radiation angle characteristics for the light emission of the light emitting apparatus. In this case, the emission area of the light emitting element in the second emission area may be large.

Since the second emission area surrounds the first emission area, the second emission area includes an area outside the first emission area in the display apparatus. In the case where a plurality of light emitting elements is disposed on the substrate, a light emitting element closer to the end of the substrate than one light emitting element is referred to as an outside light emitting element. The end of the substrate refers to an end of the substrate closest to the one light emitting element.

This embodiment allows the range of the radiation angle of the second light emitting element to be increased, providing good display quality regardless of the user’s gaze position.

### Second Embodiment

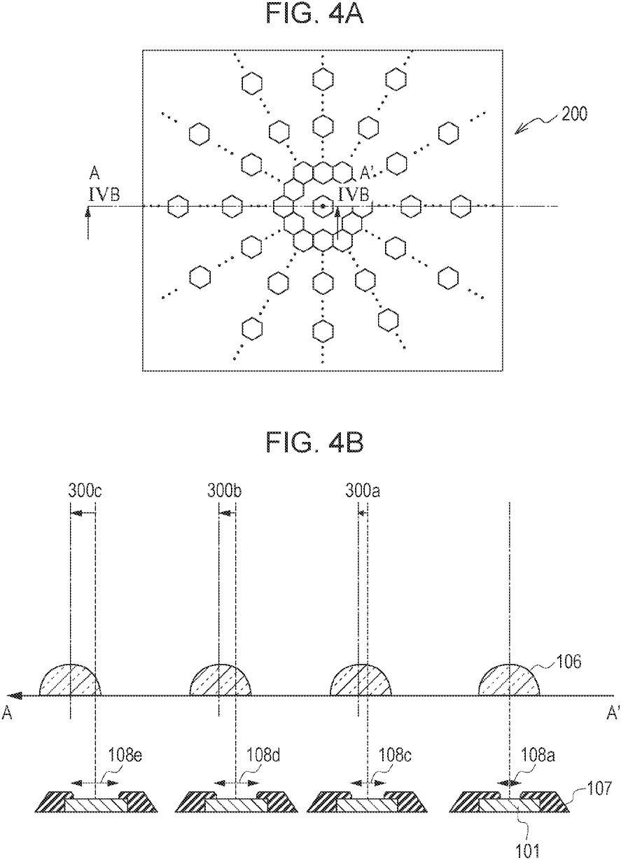

FIGS. 4A and 4B are diagrams illustrating an example of a light emitting apparatus according to an embodiment of the present disclosure. FIG. 4A is a plan view of the light emitting apparatus seen from the direction perpendicular to the principal surface of the substrate, as in FIG. 1B. A display area 200 includes a plurality of light emitting elements. The positional relationship between the emission area 108 and the microlens 106 will be described for a central portion A′ and a peripheral portion A.

FIG. 4B is part of a cross-sectional view taken along line IVB-IVB in FIG. 4A. In the cross section, some of the light emitting elements are omitted. The positional relationship between the microlens 106 and the emission area changes in the direction from A′ to A. Specifically, the microlens 106 directly above an emission area 108c deviates to the left in the drawing by a microlens shift length 300a with reference to the positional relationship between the emission area 108a and the microlens 106 directly above the emission area 108a. The emission area 108c is larger than the emission area 108a. Likewise, an emission area 108d is larger than the emission area 108c, and the microlens 106 directly above the emission area 108d deviates by an amount 300b. An emission area 108e is larger than the emission area 108d, and the microlens 106 directly above the emission area 108e deviates by an amount 300c.

In this embodiment, a first light emitting element includes the emission area 108a, a second light emitting element includes the emission area 108c, a third light emitting element includes the emission area 108d, and a fourth light emitting element includes the emission area 108e.

For example, in FIG. 4A, the light emitting elements nearer to the peripheral portion A than the central portion A′ are outer elements. In other words, the light emitting elements farther from the central portion A′ are outer light emitting elements.

Thus, the deviation of the microlens 106 may be increased continuously from the central portion A′ to the peripheral portion A of the display area.

The amount of change in the shift length may be increased with a decreasing distance to the peripheral portion A. In other words, the difference between the shift length in the emission area 108e and the shift length in the emission area 108d is larger than the difference between the shift length in the emission area 108d and the shift length in the emission area 108c. The shift length at the peripheral portion A does not have to be 0. In other words, the center of the lens 106 does not have to be disposed at the center of the emission area.

The amount of change in the shift length may be decreased with a decreasing distance to the peripheral portion A. In other words, the difference between the shift length in the emission area 108e and the shift length in the emission area 108d is smaller than the difference between the shift length in the emission area 108d and the shift length in the emission area 108c. The shift length at the peripheral portion A does not have to be 0. The shift length is larger in the emission area 108e. In other words, the center of the lens 106 does not have to be disposed at the center of the emission area.

The continuous or stepwise increase in emission area allows the light emitting apparatus to have high display quality.

### Third Embodiment

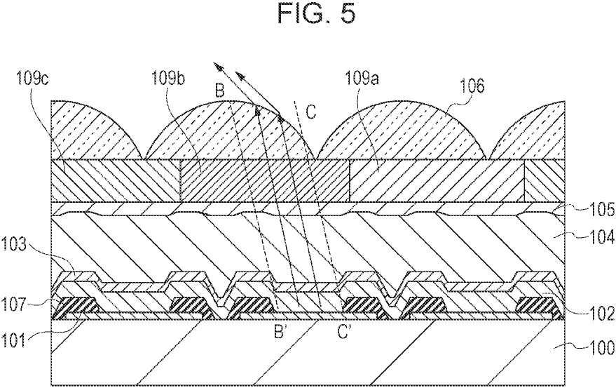

FIG. 5 is a schematic cross-sectional view of a light emitting apparatus according to an embodiment of the present disclosure. In addition to the components of the first embodiment, color filters 109a to 109c are disposed on the planarizing layer 105. Pixels including the color filters 109a to 109c individually can be regarded as subpixels, and the three subpixels can be regarded as one main pixel. That a pixel includes a color filter indicates that the light passing through the color filter is emitted from the light emitting layer of the pixel. The subpixels are particularly desirable in three kinds of color, red, green, and blue. Adding and mixing these colors enables full-color display.

The planar arrangement of the subpixels may be any of a stripe arrangement, a square arrangement, a delta arrangement, and a Bayer arrangement. Matrix arrangement of the main pixels provides a high pixel count display apparatus.

The color filters 109a to 109c are also deviated from the center of the emission areas 108b as the microlenses 106 are. The color filter 109b may be disposed on the line connecting the apex B of the microlens 106 and an end B′ of the emission area adjacent to the first light emitting element.

The color filters 109b is on the line connecting an end C of the microlens 106 and an end C′ of the emission area 108b. At least two kinds of color filter may be disposed on the line connecting the apex B of the microlens 106 directly above the emission area 108b and the emission area next to the emission area 108b. This is for the purpose of preventing the light emitted from the next emission area from passing through an unintended microlens.

This allows the light emitted from the emission area 108b to pass through the color filter 109b and to be refracted in an oblique direction by the microlens 106 and prevents the light from passing through the color filters 109a and 109c of the other subpixels, thereby improving the chromatic purity.

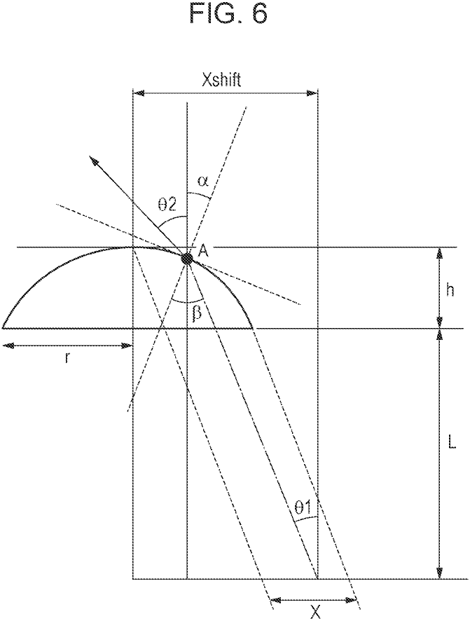

FIG. 6 is a cross-sectional view of the microlens 106 illustrating the relationship between the microlens 106 and the emission area 108. FIG. 6 illustrates the microlens 106 with a height of h, a radius of r, and a refraction index of n.

Light is emitted at an angle of θ1 from the emission area 108 and is bent at an angle of θ2 at a point A of the microlens 106. Let α be the gradient of the microlens 106 to the tangent at point A. Eq. 1 holds according to Snell’s law. In the drawing, α + θ1 is expressed as β.

$$1 \times sin \left(\text{θ} 2 + \text{α}\right) = \text{n} \times sin \left(\text{α} + \text{θ1}\right)$$

Solving Eq. 1 for θ1 gives Eq. 2.

$$\text{θ} 1 = {sin}^{- 1} \left\{sin \left(\text{θ} 2 + \text{α}\right) / \text{n}\right\} - \text{α}$$

The size X of an emission area is expresses as Eq. 3,

$$\text{X} = \text{r} - \text{h} \times tan \left(\text{θ} 1\right)$$

where Xshift is the shift length of the apex of the microlens 106 from the center of the emission area 108, and L is the distance from the emission area 108 to the microlens 106.

The size X of the emission area 108 is given by Eq. 4 from Eq. 2 and Eq. 3.

$$\text{X} = \text{r} - \text{h} \times tan \left[{sin}^{- 1} \left\{sin \left(\text{θ} 2 + \text{α}\right) / \text{n}\right\} - \text{α}\right]$$

The relationship between the angle θ1 of the light emitted from the emission area 108 and the shift amount Xshift of the apex of the microlens 106 from the center of the emission area 108 is expressed as Eq. 5.

$${tan}^{- 1} \left(\text{Xshift} / \text{h} + \text{L}\right) > \text{θ} 1$$

Table 1 shows the calculations of the length of shift of the apex of the microlens 106 from the center of the emission area 108 and the aperture ratio of the emission area 108 in a wave-optics simulation. However, actually, the protective layer 104, the color filters 109, and other members are present between the microlens 106 and the emission area 108, which can cause error.

TABLE 1

| Distance between Apex of Microlens and Center of Emission Area | Aperture Ratio of Emission Area |
|---|---|
| 0.0 µm | 33% |
| 0.5 µm | 40% |
| 1.0 µm | 46% |
| 1.5 µm | 50% |

### Configurations of Other Components in Embodiments Substrate

In this specification, the substrate 100 may be made of any material that can support the lower electrode 101, the functional layer 102, and the upper electrode 103. For example, glass, plastic, or silicone is preferable. The plastic may have flexibility. Example materials for the flexible substrate include resin and organic materials, specifically, a polyimide resin, a polyacrylic resin, and polymethylmethacrylate (PMMA) may be employed. The substrate 100 may have switching devices, such as transistors, wiring lines, and an interlayer insulating film (not shown) thereon.

### Lower Electrode

The lower electrode 101 may be made of a metal material with a visible light reflectance of 50% or more. Specific examples include aluminum (Al), silver (Ag), or other metal, and alloys of such metal and silicon (Si), copper (Cu), nickel (Ni), neodymium (Nd), or titanium (Ti). The reflecting electrode may have a barrier layer on the light-exiting surface. Examples of a material for the barrier layer include metal, such as Ti, tungsten (W), molybdenum (Mo), and gold (Au) and alloys thereof, and transparent conductive oxides, such as indium tin oxide (ITO) and indium zinc oxide (IZO). The lower electrode 101 may be a positive electrode. In this case, the upper electrode 103 may be a negative electrode. If the lower electrode 101 is a negative electrode, the upper electrode 103 may be a positive electrode.

In the above embodiments, the lower electrode 101 is a reflecting electrode and the upper electrode 103 is a light extracting electrode. Instead, the lower electrode may be a light extracting electrode. If the lower electrode is a light extracting electrode, the lower electrode has light transmittance as the upper electrode described below. Whether the electrode is a lower electrode or an upper electrode is defined by the distance from the substrate. An electrode closer to the substrate 100 including transistors for controlling light emission is the lower electrode. Insulating Layer

The insulating layer 107 is disposed so as to cover the end of the lower electrode 101 and has an opening so as to expose part of the lower electrode 101. The opening may be used as the emission area 108. The insulating layer 107 is made of an inorganic material, such as silicon nitride (SiN), silicon oxynitride (SiON), or silicon oxide (SiO). The insulating layer is also referred to as a pixel separation film or a bank.

The insulating layer 107 may be formed using a sputtering method, a chemical vapor deposition method (CVD method), or another known method. The insulating layer 107 may also be formed of an organic material, such as an acrylic resin or a polyimide resin.

### Functional Layer

The functional layer 102 includes a light emitting layer and is disposed on the lower electrode 101. The functional layer 102 can be formed using an evaporation method, a spin coat method, or another known method.

The functional layer 102 may include a plurality of layers, or a laminate formed of a plurality of layers. Examples of the plurality of layers include a hole-injection layer, a hole transport layer, an electron block layer, a light emitting layer, a hole block layer, an electron transport layer, and an electron-injection layer. Another layer, such as a charge generation layer or an electron block layer, may be disposed therebetween.

A hole injected from the positive electrode and an electron injected from the negative electrode are bonded again in the light emitting layer to emit light. The functional layer may be either an organic layer or an inorganic layer.

The light emitting layer may be have multiple layers or a single layer. In the case of the multiple light emitting layers, any of the light emitting layers can contain a red-light emitting material, a green-light emitting material, and a blue-light emitting material, allowing forming white light by mixing the color lights. Some of the organic layers may contain light-emitting materials with complementary relation, such as a blue- light emitting material and a yellow-light emitting material.

The light-emitting material may be a material made of an organic compound or a material including quantum dots. If an organic compound is used, the light emitting layer may contain a first material and a second material. The first material is a main light emitting material, which may also be referred to as dopant or guest. The second material is a material with a ratio by weight higher than that of the first material in the light emitting layer, which may also be referred to as host. Examples of the first material include a material with a Fluoranthene skeleton, a material with a pyrene skeleton, a material with a chrysene skeleton, and a material with an anthracene skeleton. The material with the anthracene skeleton has an anthracene structure and may also be referred to as “anthracene derivative”.

The functional layer 102 may be shared by a plurality of pixels. In this case, the light emitting apparatus includes a plurality of lower electrodes and one functional layer. However, this is illustrative only. The whole or part of the functional layer 102 may be patterned for each pixel.

### Upper Electrode

The upper electrode 103 is disposed above the functional layer 102 and has light transmittance. The upper electrode 103 may be a semitransmissive material having the property of transmitting part of light that has reached the surface and reflecting the other part (that is, semitransmissive reflectivity). Examples of a material for the upper electrode 103 include a transparent material, such as transparent conductive oxide, and a semitransmissive material including simple metal, such as aluminum, silver, and gold, alkali metal, such as lithium or cesium, alkali earth metal, such as magnesium, calcium, or barium, and alloy materials containing such metal materials.

The semitransmissive material may be preferably an alloy that contains magnesium or silver as the main component. The upper electrode 103, if having preferable transmittance, may have a laminate structure of the above materials. The upper electrode 103 may be disposed across a plurality of pixels.

Although the above embodiments are of a case in which the upper electrode 103 is a light extracting electrode, the upper electrode 103 may be a reflecting electrode. In this case, the upper electrode has reflectivity, as described for the lower electrode 101, and may be made of the material illustrated as the material for the lower electrode 101.

The negative electrode may be, but not limited to, a top emission element including an oxide conductive layer, such as ITO, or a bottom emission element including a reflecting electrode, such as aluminum (Al). A more preferable method for forming the negative electrode may be, but not limited to, a direct-current or alternate-current sputtering method, which allows for preferable film coverage, facilitating decreasing the resistance. Protective Layer

The protective layer 104 is disposed to cover the light emitting elements and has light transmittance. The protective layer 104 preferably contains an inorganic material having low permeability to external oxygen and moisture. Specific examples include silicon nitride (for example, SiN), silicon oxynitride (for example, SiON), silicon oxide (SiOx), aluminum oxide (for example, Al2O3), and titanium oxide (for example, TiO2). The inorganic materials, SiN, SiON, and Al2O3, are preferable in terms of protection performance. The protective layer 104 may be formed using a chemical vapor deposition method (CVD method), an atomic layer deposition method (ALD method), or a sputtering method. The protective layer 104 may have any single layer structure or laminate structure in which the above materials and the forming methods are combined having sufficient moisture block performance. For example, the protective layer 104 may have a laminate structure in which a layer formed using the ALD method and a layer formed using the sputtering method are laminated. The protective layer 104 may include a layer formed using the CVD method, a layer using the ALD method, and a layer formed using the CVD method in this order. The protective layer may be disposed across a plurality of pixels.

### Planarizing Layer

The planarizing layer 105 is disposed on the protective layer 104. The planarizing layer 105 may be made of any inorganic material or organic material having light transmittance. The planarizing layer 105 is a layer for reducing surface irregularity of the protective layer 104. The planarizing layer 105 may be omitted if the surface irregularities of the protective layer 104 is small, or the protective layer 104 itself is planarized by grinding

The planarizing layer 105 may have a lower refractive index than that of the protective layer 104. Specifically, the planarizing layer 105 may have a refractive index lower than that of the protective layer 104 and higher than 1.5. The refractive index may be from 1.5 to 1.8 (both inclusive) or from 1.5 to 1.6 (both inclusive).

Any planarizing layer disposed between the protective layer 104 and another member can be referred to as “planarizing layer”. Specific examples include a polyvinyl carbazole resin, a polycarbonate resin, a polyester resin, an acrylonitrile-butadiene-styrene (ABS) resin, an acrylate resin, a polyimide resin, a phenol resin, an epoxy resin, a silicon resin, and a urea resin.

### Optical Member

The optical member 106 is disposed on the planarizing layer 105. The optical member 106 may be a lens, specifically, microlenses. The microlenses may be small-diameter lenses. The microlenses can be formed using an exposure process or a developing process by means of a reflow method, an area coverage modulation method, an etch back method, or the like. Specifically, a film (a photoresist film) made of a material for microlenses is formed and is exposed to light and developed using a mask with a continuous tone change. Examples of the mask include a gray mask and an area coverage modulation mask made of a light shielding film with a resolution lower than or equal to the resolution of the exposure device and capable of light irradiation having continuous tones on an imaging plane by changing the dot density distribution.

The lens shape can be adjusted by performing etch back on the microlenses formed using the exposure and developing processes.

Another method for forming microlenses uses surface tension by patterning and reflowing resin and melting and solidifying the resin. If an organic layer is used as the functional layer 102, the reflow process is performed at a predetermined temperature or lower, for example, 120° C. or lower.

The microlenses 106 may be not only spherical microlenses but also aspherical microlenses, aspherical asymmetric microlens, or digital microlenses.

### Color Filter

A color filter may be provided over the protective layer 104. For example, a color filter formed in consideration of the size of the light emitting elements may be provided on another substrate and may be bonded to the substrate provided with the light emitting elements, or alternatively, the color filter may be patterned on the protective layer 104 using a photolithography technique. The color filters may be composed of a polymeric material. A typical color filter includes filters that allows red, green, and blue light to pass through. In other words, the color filter includes two or more color filters, of which a first color filter and a second color filter allow light of different wavelengths to pass through. The color filter may further include a third color filter that allows light of a different wavelength from those of the first color filter and the second color filter to pass through.

The planarizing layer 105 may be provided on or under the color filter, if provided. The materials may be the same or differ. Specific examples of the material include a polyvinyl carbazole resin, a polycarbonate resin, a polyester resin, an acrylonitrile-butadiene-styrene (ABS) resin, an acrylate resin, a polyimide resin, a phenol resin, an epoxy resin, a silicon resin, and a urea resin.

### Counter Substrate

A counter substrate may be provided on the above component. The counter substrate is disposed at a position opposite to the above-described substrate and is therefore referred to as “counter substrate”. The material for the counter substrate may be the same as that of the above-described substrate. If the above-described substrate is a first substrate, the counter substrate may be referred to as a second substrate.

The light emitting apparatus in the above embodiments may be an organic light emitting apparatus in which the functional layer is an organic compound layer. Drive Circuit

The light emitting apparatus may include a drive circuit. The drive circuit may be of an active matrix type that controls the light emissions of the first light emitting element and the second light emitting element independently. The active matrix circuit may be a voltage programing circuit or a current programing circuit. The drive circuit includes a pixel circuit for each pixel. The pixel circuit may include a light emitting element, a transistor that controls the emission luminance of the light emitting element, a transistor that controls the emission timing, a capacitor that holds the gate voltage of the transistor that controls the emission luminance, and a transistor for connecting to a ground (GND) without passing through the light emitting element.

The magnitude of the drive current may be determined according to the size of the emission area. Specifically, in causing the first light emitting element and the second light emitting element to emit light at the same luminance, the current for the first light emitting element may be smaller than the current for the second light emitting element. This is because the emission area of the first light emitting element is small, so that required current may be small.

### Applications of Light Emitting Apparatus According to Embodiment of Disclosure

The light emitting apparatus according to an embodiment of the present disclosure can be used as a component of a display apparatus or an illuminating apparatus. Other applications include an exposing source for an electrophotographic image forming apparatus, a backlight of a liquid-crystal display apparatus, and a light emitting apparatus including a color filter for a white light source.

The display apparatus may be an image information processing apparatus that includes an image input unit that receives image information from an area charge-coupled device (CCD), a linear CCD, a memory card, or the like and an information processing unit for processing the input information and that displays the input image on a display.

The display of an image pickup apparatus or an ink-jet printer may include a touch panel function. A drive method for the touch panel function may be, but is not limited to, of an infrared type, a capacitive type, a resistive type, or an electromagnetic induction type. The display apparatus may be used for the display of a multifunction printer.

Next, the display apparatus according to this embodiment will be described with reference to the drawings.

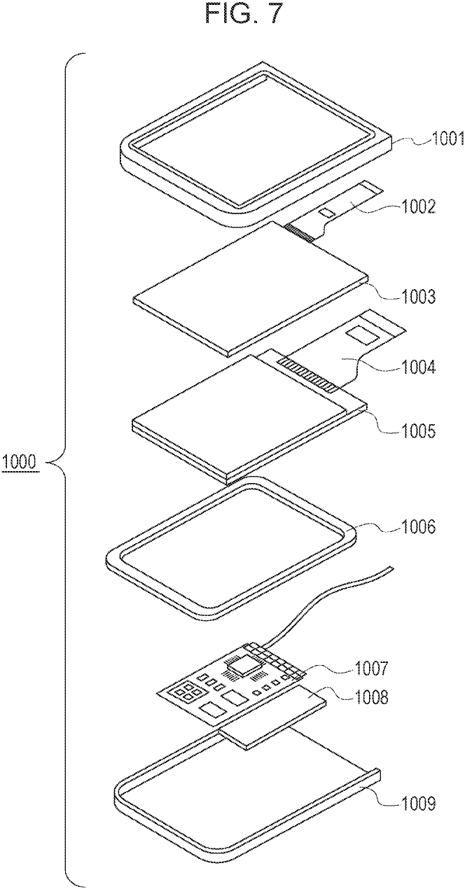

FIG. 7 is a schematic diagram illustrating an example of the display apparatus according to this embodiment. The display apparatus 1000 may include a touch panel 1003, a display panel 1005, a frame 1006, a circuit board 1007, and a battery 1008 between an upper cover 1001 and a lower cover 1009. The touch panel 1003 and the display panel 1005 connect to flexible printed circuits (FPCs) 1002 and 1004, respectively. The circuit board 1007 has transistors thereon. The battery 1008 may be omitted if the display apparatus is not a mobile device, or may be disposed at another location if it is a mobile device. The transistors may constitute a control unit for controlling the display of the display apparatus. The control unit may use a known method using a central processing unit (CPU) or the like. In other words, the display apparatus according to this embodiment includes a light emitting apparatus and a control unit for controlling the display of the light emitting apparatus.

The display apparatus according to this embodiment may include red, green, and blue color filters. The color filters may be arranged in a delta arrangement or a stripe arrangement of red, green, and blue.

The display apparatus according to this embodiment may be used for the display of a mobile terminal. In this case, the display apparatus may include both a display function and an operation function. Examples of the mobile terminal include mobile phones, such as a smartphone, a tablet, and a head mount display. If used in the display apparatus, the light emitting apparatus may be used together with a magnifying optical system.

The display apparatus according to this embodiment may be used for the display of an image pickup apparatus including an optical unit including a plurality of lenses and an image sensor that receives light passing through the optical unit. The image pickup apparatus may include a display that displays information that the image sensor captures. The display may be exposed out of the image pickup apparatus or disposed in the finder. The image pickup apparatus may be a digital camera or a digital video camera.

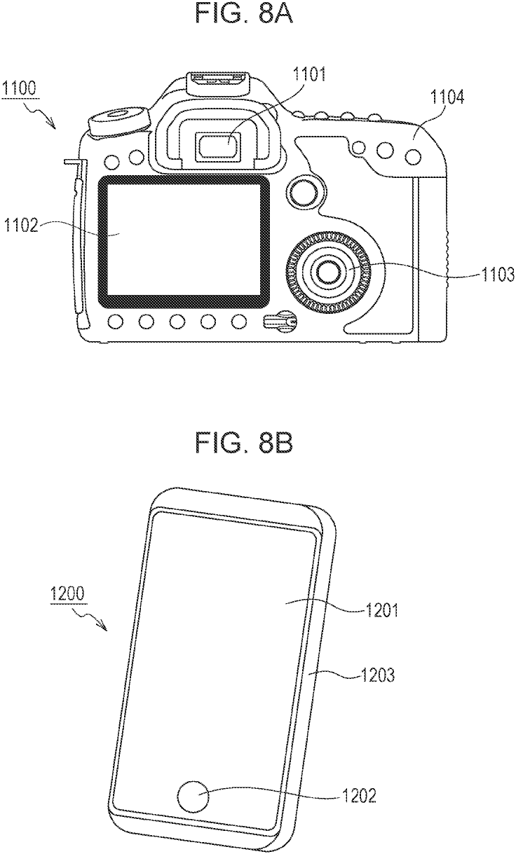

FIG. 8A is a schematic diagram illustrating an example of the image pickup apparatus according to this embodiment. The image pickup apparatus 1100 may include a viewfinder 1101, a back display 1102, an operating unit 1103, and a casing 1104. The viewfinder 1101 may include the display apparatus according to this embodiment. In this case, the display apparatus may display not only an image to be captured but also environmental information and image-pickup instructions. The environmental information may include the intensity and direction of outside light, the moving speed of the subject, and the possibility that the subject will be blocked by a shield.

The information should be displayed as fast as possible because the best timing for image capturing is short. Accordingly, a display apparatus including the organic light emitting apparatus according to an embodiment of the present disclosure may be used. This is because the organic light emitting element has a fast response speed. The display apparatus including the organic light emitting element can be used more suitably for apparatuses that require high display speed than liquid crystal display apparatuses.

The image pickup apparatus 1100 includes an optical unit (not shown). The optical unit includes a plurality of lenses and forms an image on an image sensor housed in the casing 1104. Adjusting the relative positions of the multiple lenses allows adjustment of the focus. This operation can be performed automatically. The image pickup apparatus may also be referred to as “photoelectric transducer”. The photoelectric transducer may adopt not a sequential image pickup method but a method of detecting the difference from the previous image and a method of clipping an image from recorded images.

FIG. 8B is a schematic diagram illustrating an example of the electronic apparatus according to this embodiment. The electronic apparatus 1200 includes a display 1201, an operating unit 1202, and a casing 1203. The casing 1203 may house a circuit, a printed board including the circuit, a battery, and a communication unit. The operating unit 1202 may be a button or a touch panel type reaction unit. The operating unit 1202 may be a living-organism recognition unit that recognizes a fingerprint to release the lock. The electronic apparatus including the communication unit can also be referred to as a communication apparatus. The electronic apparatus may further have a camera function by including a lens and an image sensor. An image captured using the camera function is displayed on the display. Examples of the electronic apparatus include a smartphone and a notebook personal computer (PC).

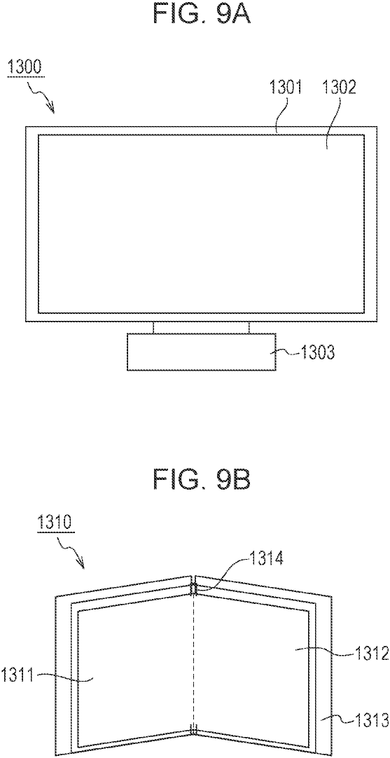

FIGS. 9A and 9B are schematic diagrams illustrating examples of the display apparatus according to this embodiment. FIG. 9A illustrates a display apparatus, such as a television monitor or a PC monitor. The display apparatus 1300 includes a frame 1301 and a display 1302. The display 1302 may include the light emitting apparatus according to this embodiment.

The display apparatus 1300 includes a base 1303 that supports the frame 1301 and the display 1302. The shape of the base 1303 is not limited to the shape shown in FIG. 9A. The lower side of the frame 1301 may serve as the base.

The frame 1301 and the display 1302 may be curved. The radius of curvature may be 5,000 mm or more and 6,000 mm or less.

FIG. 9B is a schematic diagram illustrating another example of the display apparatus according to this embodiment. A display apparatus 1310 in FIG. 9B is a foldable display apparatus whose display surface is foldable. The display apparatus 1310 includes a first display 1311, a second display 1312, a casing 1313, and a folding point 1314. The first display 1311 and the second display 1312 may each have the light emitting apparatus according to this embodiment. The first display 1311 and the second display 1312 may be one seamless display apparatus. The first display 1311 and the second display 1312 can be divided at the folding point. The first display 1311 and the second display 1312 may display different images or display one image with the first and the second displays.

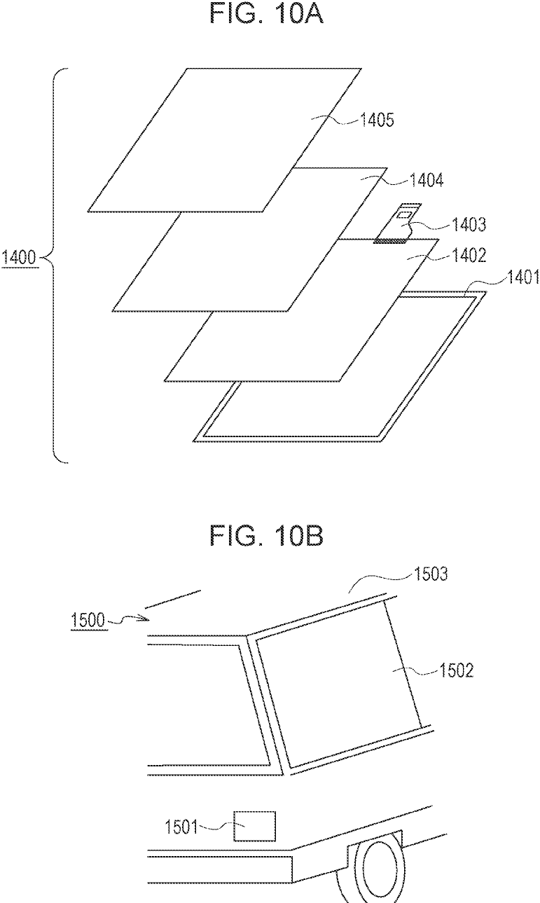

FIG. 10A is a schematic diagram illustrating an example of an illumination system according to this embodiment. The illumination system 1400 may include a casing 1401, a light source 1402, a circuit board 1403, an optical filter 1404, and a light diffusing unit 1405. The light source 1402 may include the organic light emitting element according to this embodiment. The optical filter 1404 may be a filter that increases the color rendering property of the light source 1402. The light diffusing unit 1405 can diffuse the light from the light source 1402 efficiently, for example, light up, to deliver the light to a wide area. The optical filter 1404 and the light diffusing unit 1405 may be disposed on the light emission side. A cover may be provided on the periphery as needed.

An example of the illumination system is a room lighting device. The illumination system 1400 may emit any of white, natural white, and blue to red light. The illumination system 1400 may include a dimmer circuit that controls the light. The illumination system 1400 may include the organic light emitting element according to an embodiment of the present disclosure and a power circuit connected thereto. The power circuit converts alternating-current voltage to direct-current voltage. The white light has a color temperature of 4,200 K. The natural white light has a color temperature of 5,000 K. The illumination system 1400 may include color filters.

The illumination system 1400 according to this embodiment may include a heat radiator. The heat radiator releases the heat in the apparatus to the outside. Examples include metal and liquid silicon with high specific heat.

FIG. 10B is a schematic diagram of an automobile, which is an example of a movable object according to this embodiment. The automobile includes a tail lamp, which is an example of lighting fixtures. The automobile 1500 includes a tail lamp 1501 and may be configured to light on the tail lamp 1501 at a brake operation or the like.

The tail lamp 1501 may include the organic light emitting element according to this embodiment. The tail lamp 1501 may include a protector that protects the organic EL elements. The protector may be made of any transparent material with relatively high strength, preferably, polycarbonate. The polycarbonate may contain a furandicarboxylic acid derivative, an acrylonitrile derivative, or the like.

The automobile 1500 may include a body 1503 and windows 1502 mounted thereto. The windows 1502, if not a window for checking the front and back of the automobile 1500, may include a transparent display. The transparent display may include the organic light emitting element according to this embodiment. In this case, the components of the organic light emitting element, such as electrodes, are made of transparent materials.

The movable object according to this embodiment may be a ship, an aircraft, a drone, or the like. The movable object may include a body and a lighting fixture mounted on the body. The lighting fixture may emit light for indicating the position of the body. The lighting fixture includes the organic light emitting element according to this embodiment.

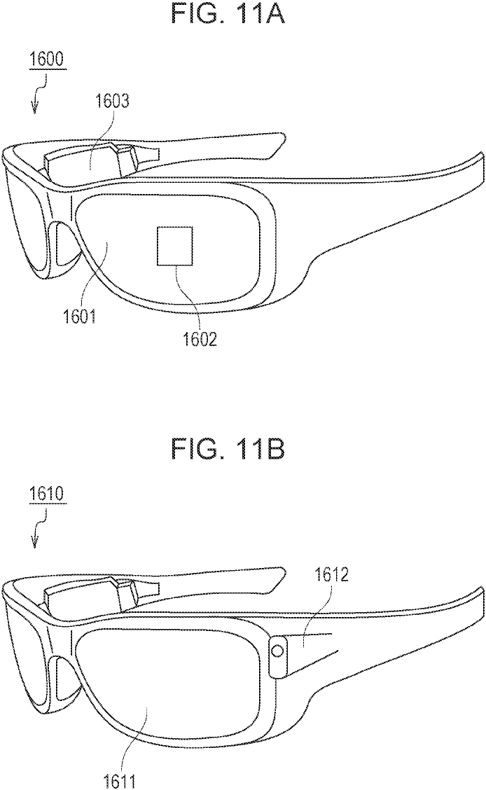

Referring to FIGS. 11A and 11B, applications of the display apparatuses of the embodiments will be described. The display apparatuses are applicable to wearable devices, such as smartglasses, head-mounted displays (HMDs), and smart contact lenses. An image-pickup display apparatus used in such applications includes an image pickup apparatus capable of photoelectrically converting visible light and a display apparatus capable of emitting visible light.

FIG. 11A illustrates a pair of glasses 1600 (smartglasses) according to an application. The pair of glasses 1600 includes an image pickup apparatus 1602, such as a complementary metal-oxide semiconductor (CMOS) sensor or a single photon avalanche diode (SPAD), on the front surface of a lens 1601. The display apparatus of each embodiment is provided on the back of the lens 1601.

The pair of glasses 1600 further includes a control unit 1603. The control unit 1603 functions as a power source for supplying electricity to the image pickup apparatus 1602 and the display apparatus according to each embodiment. The control unit 1603 controls the operation of the image pickup apparatus 1602 and the display apparatus. The lens 1601 is provided with an optical system for collecting light to the image pickup apparatus 1602.

FIG. 11B illustrates a pair of glasses (smartglasses) 1610 according to an application. The pair of glasses 1610 includes a control unit 1612. The control unit 1612 is provided with an image pickup apparatus corresponding to the image pickup apparatus 1602 and a display apparatus. A lens 1611 is provided with an optical system for projecting the light from the image pickup apparatus in the control unit 1612 and the display apparatus, and an image is projected on the lens 1611. The control unit 1612 functions as a power source for supplying electricity to the image pickup apparatus and the display apparatus and controls the operation of the image pickup apparatus and the display apparatus. The control unit 1612 may include a gaze detection unit that detects the gaze of the wearer. The gaze detection may use infrared light. An infrared emission unit emits infrared light to the eyeball of a user who is looking at the displayed image. An image sensor including a light receiving element detects the reflected light of the infrared light from the eyeball, so that an image of the eyeball is obtained. A reducing unit that reduces light from the infrared emission unit to the display in plan view reduces a decrease in image quality.

The gaze of the user to the displayed image is detected from the image of the eyeball using infrared light. The gaze detection using an image of the eyeball may use any known technique. An example is an eye-gaze tracking method based on Purkinje images obtained by the reflection of illuminated light on the cornea.

More specifically, a gaze tracking process based on pupil center corneal reflection is performed. The gaze of the user is detected by calculating a gaze vector indicating the orientation (rotation angle) of the eyeball on the basis the image of the pupil contained in the image of the eyeball and Purkinje images using pupil center corneal reflection.

A display apparatus according to an embodiment of the present disclosure may include an image pickup apparatus including a light receiving element and may control an image displayed on the display apparatus on the basis of user’s gaze information provided from the image pickup apparatus.

Specifically, the display apparatus determines a first view area that the user gazes and a second view area other than the first view area on the basis of the gaze information. The first view area and the second view area may be determined by the control unit of the display apparatus or may be received from an external control unit. The display resolution of the first view area in the display area of the display apparatus may be set higher than the display resolution of the second view area. In other words, the resolution of the second view area may be set lower than the resolution of the first view area.

The display area may include a first display area and a second display area different from the first display area. A higher priority area may be determined from the first display area and the second display area on the basis of the gaze information. The first view area and the second view area may be determined by the control unit of the display apparatus or may be received from an external control unit. The resolution of a higher priority area may be set higher than the resolution of the area other than the higher priority area. In other words, the resolution of the lower priority area may be set low.

The determination of the first view area and the higher priority area may use artificial intelligence (AI). The AI may be a model configured to estimate the angle of the gaze and the distance to the object of the gaze from an image of the eyeball using the image of the eyeball and the direction in which the eyeball in the image gazes actually. The AI program may be installed in the display apparatus, the image pickup apparatus, or an external apparatus. If the AI program is installed in an external apparatus, the AI program is sent to the display apparatus via communication.

Display control based on visual recognition allows application to smartglasses that further includes an image pickup apparatus that captures an external image. Smartglasses can display captured external information in real time.

Thus, the use of an apparatus including the organic light emitting element according to this embodiment allows stable display with high image quality even for long time display.

The present disclosure provides a light emitting apparatus capable of providing stable display quality regardless of the user’s gaze position even with low power consumption using a lens.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light emitting apparatus comprising:
a substrate including a principal surface;
a first light emitting element disposed on the principal surface;
a second light emitting element disposed on the principal surface;
a first lens that receives light emitted from the first light emitting element; and
a second lens that receives light emitted from the second light emitting element,
wherein the first light emitting element and the second light emitting element each include a lower electrode, an upper electrode, and an organic compound layer disposed between the lower electrode and the upper electrode,
wherein, in a direction parallel to the principal surface, a distance between a middle point of an emission area of the second light emitting element and an apex of the second lens is larger than a distance between a middle point of an emission area of the first light emitting element and an apex of the first lens,
wherein the emission area of the second light emitting element is larger than the emission area of the first light emitting element, and
wherein the lower electrode of the second light emitting element is larger than the lower electrode of the first light emitting element.

2. The light emitting apparatus according to claim 1, further comprising:
a third light emitting element; and
a third lens that receives light emitted from the third light emitting element,
wherein, in the direction parallel to the principal surface, a distance between a middle point of an emission area of the third light emitting element and an apex of the third lens is larger than the distance between the middle point of the emission area of the second light emitting element and the apex of the second lens, and
wherein the emission area of the third light emitting element is larger than the emission area of the second light emitting element.

3. The light emitting apparatus according to claim 1,
wherein the first light emitting element includes:
a lower electrode, a light emitting layer, an upper electrode in this order; and
a first insulating layer and a second insulating layer that individually cover both ends of the lower electrode,
wherein the middle point of the emission area of the first light emitting element is a middle point of a line segment connecting an end of the first insulating layer and an end of the second insulating layer.

4. The light emitting apparatus according to claim 1, wherein the first lens and the second lens are disposed on a light extracting side of the light emitting apparatus farther from the first light emitting element and the second light emitting element.

5. The light emitting apparatus according to claim 1,
wherein the emission area of the light emitting apparatus includes a first emission area and a second emission area surrounding the first emission area, and
wherein the first light emitting element is disposed in the first emission area, and the second light emitting element is disposed in the second emission area.

6. The light emitting apparatus according to claim 1,
wherein the emission areas of the first light emitting element and the second light emitting element are polygonal, and
wherein at least one side of the polygonal emission area of the second light emitting element is disposed inner than the polygonal emission area of the first light emitting element.

7. The light emitting apparatus according to claim 6,
wherein, the at least one side of the emission area of the second light emitting element disposed inner than the polygonal emission area of the first light emitting element includes two sides of the polygon, and
wherein, the two sides are farthest from each other among the sides of the polygon.

8. The light emitting apparatus according to claim 6,
wherein the first light emitting element is in the first emission area of the light emitting apparatus, and the second light emitting element is in the second emission area surrounding the first emission area,
wherein, in the polygonal emission area of the second light emitting element, the at least one side disposed inner than the emission area of the first light emitting element is one side of the polygon, and
wherein the one side is closest to the first emission area among the sides of the polygon.

9. The light emitting apparatus according to claim 1,
wherein the emission area of the light emitting apparatus includes a first emission area and a second emission area surrounding the first emission area, and
wherein the first light emitting element is disposed in the first emission area, and the second light emitting element is disposed in the second emission area,
the light emitting apparatus further comprising:
a second color filter that receives light emitted from the second light emitting element;
a fourth light emitting element disposed next to the second light emitting element; and
a fourth color filter that receives light from the fourth light emitting element and that transmits light of a wavelength different from a wavelength of the second color filter,
wherein the second color filter and the fourth color filter are disposed on a line segment connecting an end of the second optical member adjacent to the first light emitting element and an end of the emission area of the fourth light emitting element adjacent to the first light emitting element.

10. The light emitting apparatus according to claim 1, wherein a width X of the second emission area is expressed as
$$\text{X} = \text{r} - \text{h} \times tan \left[{sin}^{- 1} \left\{sin \left(\text{θ} 2 + \text{α}\right) / \text{n}\right\} - \text{α}\right] {tan}^{- 1} \left(\text{Xshift} / \text{h+L}\right) > \text{θ} 1 ,$$
where h is a height of the second lens, r is a radius of the second lens, n is a refractive index of the second lens, θ1 is an angle of light emitted from the second emission area bent by the second lens, α is an angle of the second lens at a point at which the light emitted from the second emission area is bent by the second lens, θ2 is an angle of the bent light, Xshift is a shift length of an apex of the second lens from a center of the second emission area, and L is a distance from the second emission area to the second lens.

11. The light emitting apparatus according to claim 1, wherein the emission area of the first light emitting element is circular in plan view of the substrate.

12. A light emitting apparatus comprising:
a substrate including a principal surface;
a first emission area including a first light emitting element disposed on the principal surface; and
a second emission area including a second light emitting element disposed on the principal surface and surrounding the first emission area,
wherein the first light emitting element and the second light emitting element each include a lower electrode, an upper electrode, and an organic compound layer disposed between the lower electrode and the upper electrode,
wherein an emission area of the second light emitting element is larger than an emission area of the first light emitting element, and
wherein the lower electrode of the second light emitting element is larger than the lower electrode of the first light emitting element.

13. The light emitting apparatus according to claim 12, wherein the first light emitting element and the second light emitting element emit light of the same color.

14. The light emitting apparatus according to claim 12,
wherein the first light emitting element and the second light emitting element include a first electrode, a second electrode, an organic compound layer disposed between the first electrode and the second electrode, a first insulating layer in contact with one end of the first electrode, and a second insulating layer in contact with another end of the first electrode, and
wherein, in a cross section perpendicular to the principal surface of the substrate, a distance between the first insulating layer and the second insulating layer is the emission area.

15. The light emitting apparatus according to claim 12, further comprising:
a first lens that receives light emitted from the first light emitting element; and
a second lens that receives light emitted from the second light emitting element,
wherein, in a direction parallel to the principal surface, a distance between a middle point of an emission area of the second light emitting element and an apex of the second lens is larger than a distance between a middle point of an emission area of the first light emitting element and an apex of the first lens.

16. The light emitting apparatus according to claim 12, wherein the first lens and the second lens are disposed on a light extracting side of the light emitting apparatus farther from the first light emitting element and the second light emitting element.

17. The light emitting apparatus according to claim 1, wherein the light emitting apparatus is of an active matrix type in which light emission of the first light emitting element and the second light emitting element are controlled independently.

18. A display apparatus comprising:
the light emitting apparatus according to claim 1; and
a control unit that controls display of the light emitting apparatus.

19. An image pickup apparatus comprising:
an optical unit including a plurality of lenses;
an image sensor that receives light passing through the optical unit; and
a display unit that displays an image taken by the image sensor,
wherein the display unit includes the light emitting apparatus according to claim 1.

20. An electronic apparatus comprising:
a display unit including the light emitting apparatus according to claim 1;
a casing in which the display unit is disposed; and
a communication unit disposed in the casing, the communication unit communicating with outside.

21. An illuminating apparatus comprising:
a light source including the light emitting apparatus according to claim 1; and
a light diffusion unit or an optical film that transmits light emitted from the light source.

22. A movable object comprising:
a lighting fixture including the light emitting apparatus according to claim 1; and
a body including the lighting fixture.
